(19) United States
(12) Patent Application Publication
(10) Pub. No.: US 2026/0334123 A1
(43) Pub. Date: Oct. 22, 2026

(54) SUBSTRATE PROCESSING METHOD

(71) Applicant: Kao Corporation, Tokyo (JP)

(72) Inventors: Yuta MURASE, Wakayama (JP); Shota OKAZAKI, Wakayama (JP)

(73) Assignee: Kao Corporation, Tokyo (JP)

(21) Appl. No.: 19/109,025

(22) PCT Filed: Sep. 5, 2023
(86) PCT No.: PCT/JP2023/032410

§ 371 Date: Mar. 5, 2025

(30) Foreign Application Priority Data
Sep. 6, 2022 (JP) 2022-141483

(51) Int. Cl. H10P 70/00; C23G 1/20

(52) U.S. Cl. CPC H10P 70/27; C23G 1/20

(57) ABSTRACT

In one aspect, provided is a method for treating a substrate after etching which allows the water-insoluble matter produced to be dissolved.

An aspect of the present disclosure relates to a method for treating a substrate after etching. The method includes cleaning a substate to be treated with a basic cleaning composition that contains a basic compound and water and has a pH of 10 or more. The substrate to be treated has a metal layer containing a Group 6 element metal and has been etched with an etchant containing phosphoric acid, nitric acid, water, and an organic amine.

### TECHNICAL FIELD

The present disclosure relates to a method for treating a substrate after etching.

### BACKGROUND ART

The manufacturing process of a semiconductor device includes a step of etching a layer to be etched to form a predetermined pattern. The layer to be etched contains at least one metal selected from, e.g., tungsten, tantalum, zirconium, hafnium, molybdenum niobium, ruthenium, osmium, rhenium, rhodium, copper, nickel, cobalt, titanium, titanium nitride, alumina, aluminum, or iridium.

In the field of semiconductor, wiring has been required to be finer and more complicated due to a high level of integration in recent years. There is also a growing demand for patterning technology and etchants, and various etching methods have been proposed.

For example, JP2013-237873A (Patent Document 1) proposes a method for etching a metal film with an etchant compostions, the metal film having at least one layer of a metal thin film made of molybdenum or a molybdenum alloy. The etchant composition contains phosphoric acid, nitric acid, polyalkylene polyamine having three or more amino groups in a molecular, and water.

JP2019-165225A (Patent Document 2) proposes a method for etching a tungsten-containing material and a TiN-containing material with an etchant composition. The etchant composition contains water, an oxidizing agent such as phosphoric acid or nitric acid, and at least one component selected from a fluorine-containing etching compound, an organic solvent such as acetic add, a chelating agent, a corrosion inhibitor such as polyethyleneimine or a surfactant.

JP2012-49535A (Patent Document 3)proposes a method for etching a multilayer film such as a Cu/Mo laminated metal film with an etchant composition. The etchant composition contains 50 to 80% by weight of phosphoric acid, 0.5 to 10% by weight of nitric acid, 5 to 30% by weight of acetic acid, and 0.01 to 5% by weight of imidazole with respect to the total weight of the compostions.

### DISCLOSURE OF INVENTION

An aspect of the present disclosure relates to a method for treating a substrate after etching. The method includes cleaning a substrate to be treated with a basic cleaning composition that contains a basic compound and water and has a pH of 10 or more. The substrate to be treated has a metal layer containing a Group 6 element metal and has been etched with an etchant containing phosphoric acid, nitric acid, water, and an organic amine.

### DESCRIPTION OF THE INVENTION

A substrate is usually washed with water after etching to remove etching residues or the like on the substrate. When a substrate is etched with an etchant containing an organic amine, as disclosed in Patent Documents 1 to 3, and then the etched substrate is washed with water, water insoluble matter is produced and adheres to the substrate surface or causes clogging of filters that would be used for recycling of a cleaning composition.

With the foregoing in mind, in one aspect, the present disclosure provides a method for treating a substrate after etching, which allows the water insoluble matter produced to be dissolved.

In one aspect, the present disclosure can provide the method for treating a substrate after etching, which allows the water insoluble matter produced to be dissolved.

In one aspect, the present disclosure is based on the findings that the water insoluble matter produced can be dissolved by using a specific basic cleaning composition to clean a substrate that has been etched with an etchant composition containing an organic amine.

In one aspect, the present disclosure relates to a method for treating a substrate after etching (also referred to as a “substrate treating method of the present disclosure” in the following). The method includes cleaning a substrate to be treated with a basic cleaning composition that contains a basic compound and water and has a pH of 10 or more. The substrate to be treated has a metal layer containing a Group 6 element metal and has been etched with an etchant containing phosphoric acid, nitric acid, water, and an organic amine.

The details of the mechanism of the effect of the present disclosure are not fully clear, but can be assumed as follows.

After the etching treatment, the Group 6 element metal dissolved in the etchant reacts with phosphoric acid to produce heteropoly acid. A complex salt composed of the heteropoly acid as a product and the organic amine as a constituent of the etchant is hardly soluble in water. Consequently, water insoluble matter will be formed when the etched substrate is washed with water. In the present disclosure, the use of the basic cleaning composition that contains a basic compound and water and has a pH of 10 or more to clean the substrate may promote dissociation (salt exchange) of the heteropoly acid from the organic amine and decomposition (hydrolysis) of the heteropoly acid, making it possible to remove (dissolve) the water insoluble matter.

However, the present disclosure should not be interpreted solely by the above mechanism.

### [Cleaning Process]

The substrate treating method of the present disclosure includes cleaning a substrate to be treated with a basic cleaning composition (also referred to as a “basic cleaning composition of the present disclosure” in the following) that contains a basic compound and water and has a pH of 10 or more, which is also referred to simply as a “cleaning process” in the following.

In one or more embodiments, the substrate treating method of the present disclosure is a substrate cleaning method. Specifically, in one or more embodiments, the substrate treating method of the present disclosure is a substrate cleaning method that includes cleaning a substrate to be treated with the basic cleaning composition of the present disclosure.

In one or more embodiments, the cleaning process using the basic cleaning composition of the present disclosure is also referred to as an alkaline cleaning process.

Examples of the cleaning method in the cleaning process include immersion cleaning, ultrasonic cleaning, oscillation cleaning, spray cleaning, and cleaning using the rotation of, e.g., a spinner. These cleaning methods may be used alone or in combination of two or more.

In the cleaning process, the temperature of the cleaning composition is, e.g., 0° C. or more and 100° C. or less.

In the cleaning process, the cleaning time is, e.g., 10 seconds or more and 120 minutes or less.

In the cleaning process, ultrasonic irradiation may be applied when the cleaning composition comes into contact with the substrate to be treated. The ultrasonic irradiation is, e.g., 20 to 5000 KHz.

Examples of the device for the cleaning process include an immersion cleaner, an ultrasonic cleaner, an oscillation cleaner, a spray cleaner, and a cleaner using the rotation of, e.g., a spinner.

In one or more embodiments, the substrate treating method of the present disclosure may include rinsing the substrate to be treated with water and drying the rinsed substrate after the cleaning process.

In one or more embodiments, the substrate treating method of the present disclosure may include rinsing the substrate to be treated with water after the cleaning process.

In one or more embodiments, the substrate treating method of the present disclosure may include etching a substrate (substrate to be treated) that has a metal layer containing a Group 6 element metal with an etchant containing phosphoric acid, nitric acid, water, and an organic amine, which is also referred to simply as an “etching process” in the following.

Examples of the etching method in the etching process include immersion etching and single wafer etching.

In the etching process, the temperature (etching temperature) of the etchant composition is, e.g., 0° C. or more and 100° C. or less.

In the etching process, the etching time may be set to, e.g., 1 minute or more and 180 minutes or less.

The etchant used in the etching process may be any etchant that contains phosphoric acid, nitric acid, water, and an organic amine.

In one or more embodiments, the etchant may contain acid containing phosphoric acid and nitric acid. In other words, in one or more embodiments, the etchant may further contain acid other than phosphoric acid and nitric acid. Examples of the acid other than phosphoric acid and nitric acid include inorganic acids such as sulfuric acid and hydrochloric acid, and organic acids such as citric acid, formic acid, tartaric acid, oxalic acid, sulfamic acid, acetic acid, and malonic acid.

Examples of the organic amine compound contained in the etchant include at least one organic amine compound selected from the group consisting of polyalkyleneimine, a polymer having a constitutional unit derived from diallylamine, polyalkylene polyamine, alkylamine, alkanolamine, alicyclic amine, aromatic amine, and amino acid.

### <Substrate to be Treated>

In one or more embodiments, the substrate to be treated is a substrate that has a metal layer containing a Group 6 element metal and has been etched with an etchant containing phosphoric acid, nitric acid, water, and an organic amine.

In one or more embodiments, the metal layer to be etched with the etchant composition contains a Group 6 element metal. The Group 6 element metal may be at least one selected from the group consisting of chromium (Cr), molybdenum (Mo), tungsten (W), and seaborgium (Sg). The metal layer may be composed of either only the Group 6 element metal or an alloy containing the Group 6 element metal. The metal layer may be, e.g., a tungsten film or a molybdenum film. The thickness of the metal layer is, e.g., 1 nm to 1 mm.

The substrate to be treated may be, e.g., a substrate having a tungsten film or a substrate having a molybdenum film. Examples of the substrate include at least one substrate selected from a semiconductor wafer, a substrate for a liquid crystal display, a substrate for a plasma display, a substrate for an FED (field emission display), a substrate for an optical disk, a substrate for a magnetic disk, a substrate for a magneto optical disk, a substrate for a photomask, a ceramic substrate, and a substrate for a solar cell.

### <Basic Cleaning Composition>

The basic cleaning composition of the present disclosure is an aqueous cleaning composition that contains a basic compound and water and has a pH of 10 or more.

### (Basic Compound)

The basic compound contained in the basic cleaning composition of the present disclosure may be at least one of an inorganic alkali or an organic alkali. Examples of the inorganic alkali include ammonia and alkali metal hydroxides such as potassium hydroxide and sodium hydroxide. Examples of the organic alkali include an organic amine or a salt thereof, such as tetramethylammonium hydroxide (TMAH). Among them, the basic compound preferably incudes at least one selected from the group consisting of ammonia, an alkali metal hydroxide, and an organic amine or a salt thereof in terms of basic strength. The basic compound may be one type or a combination of two or more types.

The content of the basic compound in the basic cleaning composition of the present disclosure is preferably 0.01% by mass or more, more preferably 0.05% by mass or more, and further preferably 0.1% by mass or more from the viewpoint of improving the ability of the basic cleaning composition to dissolve water-insoluble matter. Furthermore, the content of the basic compound is preferably 100% by mass or less, more preferably 99% by mass or less, and further preferably 98% by mass or less from the viewpoint of improving the ability of the basic cleaning composition to dissolve water insoluble matter. More specifically, the content of the basic compound is preferably 0.01% by mass or more and 100% by mass or less, more preferably 0.05% by mass or more and 99% by mass or less, and further preferably 0.1% by mass or more and 98% by mass or less. When the basic compound is a combination of two or more types, the content the basic compound is the total amount of the two or more types.

### (Water)

Water contained in the basic cleaning composition of the present disclosure may be, e.g., distilled water, ion exchanged water, pure water, or ultrapure water.

The content of water in the basic cleaning composition of the present disclosure is preferably 0% by mass or more, more preferably 1% by mass or more, and further preferably 2% by mass or more from the viewpoint of improving the ability of the basic cleaning composition to dissolve water-insoluble matter. Furthermore, the content of water is preferably 99.99% by mass or less, more preferably 99.95% by mass or less, and further preferably 99.90% by mass or less from the viewpoint of improving the ability of the basic cleaning composition to dissolve water insoluble matter. More specifically, the content of water is preferably 0% by mass or more and 99.99% by mass or less, more preferably 1% by mass or more and 99.95% by mass or less, and further preferably 2% by mass or more and 99.90% by mass or less.

### (Other Components)

The basic cleaning composition of the present disclosure may contain other components as needed in addition to the basic compound and water from the viewpoint of improving the cleanability. The other components include, e.g., a surfactant, a chelating agent, an antifoaming agent, alcohols, an antiseptic, and an antioxidant.

The pH of the basic cleaning composition of the present disclosure is 10 or more, preferably 11 or more, and also preferably 14 or more from the viewpoint of improving the ability of the basic cleaning composition to dissolve water insoluble matter. In the present disclosure, the pH of the basic cleaning composition is a value at a temperature of 25° C. and can be measured with a pH meter. Specifically, the pH of the basic cleaning composition can be measured by a method as described in Examples.

The basic cleaning composition of the present disclosure can be produced by blending, e.g., the basic compound and water, and optionally the other components, with a known method. In the context of the present disclosure, the term “blending” includes mixing the basic compound and water, and optionally the other components, simultaneously or in any order. The blending amount of each component in the production method of the basic cleaning composition of the present disclosure may be the same as the content of each component in the basic cleaning composition of the present disclosure, as described above.

In the context of the present disclosure, in one or more embodiments, the “content of each component in the cleaning composition” means the amount of each component in the cleaning composition that is to be used in the cleaning process, i.e., the amount of each component in the cleaning composition at the time the cleaning composition starts to be used for cleaning (at the time of use).

The basic cleaning composition of the present disclosure may be concentrated by reducing its water content so as not to impair the storage stability. Such a concentrate of the basic cleaning composition is preferably diluted by a dilution factor of 10 or more and 100 or less from the viewpoint of transportation and storage as well as storage stability. The concentrate of the basic cleaning composition may be diluted with water so that the content of each component is within the above range at the time of use (i.e., at the time of cleaning). In the present disclosure, the concentrate of the basic cleaning composition “at the time of use” or “at the time of cleaning” indicates the state in which the concentrate is diluted. When the basic cleaning composition is prepared as a concentrate, the substrate treating method of the present disclosure may further include diluting the concentrate of the basic cleaning composition.

The substrate treating method of the present disclosure may include washing (rinsing) the substrate to be treated with water (also referred to as a “water washing process” in the following) before the cleaning process (alkali cleaning process).

In one or more embodiments, the water washing process is a water rinsing process.

An aqueous composition used in the water washing process may include, e.g., water such as distilled water, ion exchanged water, pure water, or ultrapure water. The aqueous composition may also contain a low boiling point organic solvent such as ethanol or isopropanol in addition to water.

The temperature of the aqueous composition in the water washing process is not particularly limited and is preferably 5° C. or more and 80° C. or less, and more preferably 10° C. or more and 60° C. or less. Examples of the washing method in the water washing process include spray washing, soak washing, and application of the aqueous composition with, e.g., a spray.

An embodiment of the substrate treating method of the present disclosure includes cleaning a substrate to be treated, which has been etched with an etchant containing phosphoric acid, nitric acid, water, and an organic amine, by using a basic cleaning composition that contains a basic compound and water and has a pH of 10 or more.

In one or more embodiments, the substrate treating method of the present disclosure can be used in the manufacturing process of electronic devices, particularly electrode wiring for semiconductor devices of, e.g., liquid crystal displays, or semiconductor memories such as nonvolatile memories including 3D-NAND flash memories.

In one or more embodiments, the substrate treating method of the present disclosure can be suitably used for the formation of single-layer metal wiring or multilayer metal wiring. As a result, the wiring can have a cross-section with a good forward tapered shape when viewed from the side.

### EXAMPLES

Hereinafter, the present disclosure will be described in detail by way of examples. However, the present disclosure is not limited to the following examples.

### 1. Preparation of Cleaning Composition

### (Basic Cleaning Compositions of Examples 1 to 7, Comparative Examples 1 to 3)

Basic cleaning compositions of Examples 1 to 7 and Comparative Examples 1 to 3 were each prepared by blending the basic compound shown in Table 1 and water to have a pH shown in Table 1. Table 1 shows the pH of each of the basic cleaning compositions.

### (Basic Cleaning Compositions of Comparative Examples 4 to 5)

Water is used as a cleaning composition in Comparative Examples 4 to 5.

The cleaning compositions were prepared by using the following components.

### (Basic Compound)

Ammonia [manufactured by KANTO CHEMICAL CO., INC.]
KOH: potassium hydroxide [manufactured by FUJIFILM Wako Pure Chemical Corporation]
TMAH: tetramethylammonium hydroxide [manufactured by FUJIFILM Wako Pure Chemical Corporation]

### (Water)

Water [ultrapure water produced by using a continuous pure water production system (PURECONTI PC-2000VRL) and a subsystem (MAKUACE KC-05H), both manufactured by Kurita Water Industries Ltd.]

### 2. Method for Measuring Each Parameter

### [pH of Cleaning Composition]

The pH value of the cleaning composition at 25° C. was measured with a pH meter (manufactured by DKK-TOA CORPORATION). Specifically, the pH value was obtained 1 minute after the electrode of the pH meter was immersed in the etchant.

### 3. Evaluation

### [Evaluation of Ability of Cleaning Composition to Dissolve Water Insoluble Matter (Property of Dissolving Water Insoluble Matter)]

The ability of the cleaning composition to dissolve water insoluble matter (i.e., the property of dissolving water insoluble matter) was evaluated based on the following experimental procedure.

### Examples 1 to 7, Comparative Examples 1 to 5

In Examples 1 to 7 and Comparative Examples 1 to 5, the ability of the cleaning composition to dissolve water insoluble matter (i.e., the property of dissolving water-insoluble matter) was evaluated under the experimental procedure that assumed that the etched substrate was rinsed with water (water washing), followed by alkaline cleaning. Table 1 shows the results.

### Experimental Procedure

1) In a 30 mL glass bottle was placed 10 mL of etchant containing 62% by mass of phosphoric acid, 5% by mass of nitric acid, 12% by mass of water, 2% by mass of organic amine, and 19% by mass of acetic acid and 50 mg of metal powder, which was a component to be etched shown in Table 1. The mixture was heated (45° C., water bath) until the metal powder was completely dissolved and the solution became transparent. The organic amine was polyethyleneimine (number average molecular weight: 600, “EPOMIN SP-006” manufactured by NIPPON SHOKUBAI CO., LTD.)

2) 0.2 g of the treated etchant in the step 1) and 10 mL of pure water were placed in a 100 mL beaker, and then mixed thoroughly.

3) The mixed solution obtained in the step 2) was centrifuged (10000 ppm, 10 minutes) to remove the supernatant so that the precipitates were collected.

4) 10 mL of the cleaning composition in each of Examples 1 to 7 and Comparative Examples 1 to 5 was added to several tens of mg of the precipitates, and the property of dissolving water insoluble matter was visually identified. Specifically, the property of dissolving water insoluble matter was determined by the presence or absence of the Tyndall phenomenon using red laser irradiation. If no red line was observed in the solution, it was confirmed that the cleaning composition had the ability to dissolve water insoluble matter (i.e., the cleaning composition was able to dissolve the water-insoluble matter produced). This result is represented by “A” in Table 1. On the other hand, if a red line was observed in the solution, it was confirmed that the cleaning composition lacked the ability to dissolve water insoluble matter. This result is represented by “B” in Table 1.

### [Evaluation of Filter Permeability]

### Examples 1 to 7, Comparative Examples 1 to 5

In Examples 1 to 7 and Comparative Examples 1 to 5, the filter permeability was evaluated under the experimental procedure that assumed that the etched substrate was rinsed with water (water washing), followed by alkaline cleaning. Table 1 shows the results.

### Experimental Procedure

1) In a 30 mL glass bottle was placed 10 mL of etchant containing 62% by mass of phosphoric acid, 5% by mass of nitric acid, 12% by mass of water, 2% by mass of organic amine, and 19% by mass of acetic acid and 50 mg of metal powder, which was a component to be etched shown in Table 1. The mixture was heated (45° C.), water bath) until the metal powder was completely dissolved and the solution became transparent. The organic amine was polyethyleneimine (number average molecular weight: 600, “EPOMIN SP-006” manufactured by NIPPON SHOKUBAI CO., LTD.)

2) 50 g of pure water and 2.5 g of the treated etchant in the step 1) were placed in a 100 mL beaker, and then mixed thoroughly.

3) The entire suspension obtained in the step 2) was drawn into a syringe (volume: 60 mL, diameter: 3 cm), and a filter with a pore size of 0.2 μm and a filtration area of 4 cm² (hydrophilic PTFE 0.2 μm (pore size) filter, type: 25HP020AN, manufactured by ADVANTEC) was attached to the syringe. This syringe was fixed to an air cylinder, and the plunger of the syringe was pushed at a constant air pressure (filtration pressure) of 0.2 MPa to force 50 mL of the suspension to fully pass through the filter.

4) The filter was removed from the syringe after the filtration in the step 3), and 50 mL of the cleaning composition shown in Table 1 was drawn into the syringe. The filter that had just been removed was reattached to the syringe, and the plunger of the syringe was pushed at a constant air pressure (filtration pressure) of 0.2 MPa to force the cleaning composition to fully pass through the filter again.

5) The filter was removed from the syringe after the filtration in the step 4), and 50 mL of pure water was drawn into the syringe. The filter that had just been removed was reattached to the syringe, and the plunger of the syringe was pushed at a constant air pressure (filtration pressure) of 0.2 MPa. The time it took for the 50 mL pure water to fully pass through the filter was measured, and a filtration rate (g/min cm²) was calculated. Table 1 shows the results. The higher the filtration rate, the better the filter permeability (i.e., the cleaning composition was able to dissolve the water insoluble matter produced).

### [Evaluation of Cleanability of Cleaning Composition for Substrate]

### Examples 1 to 7, Comparative Examples 1 to 5

The cleanability of the cleaning composition for a substrate was evaluated under the following experimental procedure. Table 1 shows the results.

### Experimental Procedure

1) In a 30 mL glass bottle was placed 10 mL of etchant containing 62% by mass of phosphoric acid, 5% by mass of nitric acid, 12% by mass of water, 2% by mass of organic amine, and 19% by mass of acetic acid and 50 mg of metal powder, which was a component to be etched shown in Table 1. The mixture was heated (45° C., water bath) until the metal powder was completely dissolved and the solution became transparent. The organic amine was polyethyleneimine (number average molecular weight: 600, “EPOMIN SP-006” manufactured by NIPPON SHOKUBAI CO., LTD.)

2) The substrate shown in Table 1 and 1.0 g of the treated etchant in the step 1) were placed in a 100 mL beaker, to which 50 mL of pure water was added. Upon the addition of water, precipitates were formed and residues adhered to the substrate.

3) The substrate to which the precipitates had adhered in the step 2) was placed in a 100 mL beaker, and 60 mL of the cleaning composition in each of Examples 1 to 7 and Comparative Examples 1 to 5 was added. Then, the property of dissolving the residues on the substrate was visually identified.

As a result, the cleaning composition had a rating of “A” if the residues on the substrate were no longer visible within 3 minutes after the immersion of the substrate in the cleaning composition, “B” if the residues on the substrate were no longer visible in more than 3 minutes but less than 30 minutes after the immersion of the substrate in the cleaning composition, and “C” if the residues on the substrate were visible even after 30 minutes.

TABLE 1

| | | Water rinsing | Cleaning process | | Ability of cleaning | | Cleanability of |
|---|---|---|---|---|---|---|---|
| | | process | Cleaning composition | | composition to | Filter | cleaning |
| | Component | (water washing | Basic compound | | dissolve water- | permeability | composition for |
| | to be etched | process) | Type | pH | insoluble matter | g/min · cm² | substrate |
| Ex. 1 | Mo | water rinsing | ammonia | 11 | A | 69 | A |
| Ex. 2 | W | water rinsing | ammonia | 11 | A | 61 | A |
| Ex. 3 | Mo | water rinsing | KOH | 11 | A | 59 | A |
| Ex. 4 | Mo | water rinsing | TMAH | 11 | A | 71 | A |
| Ex. 5 | Mo | water rinsing | ammonia | 10 | A | 32 | B |
| Ex. 6 | Mo | water rinsing | KOH | 10 | A | 27 | B |
| Ex. 7 | Mo | water rinsing | TMAH | 10 | A | 36 | B |
| Comp. Ex. 1 | Mo | water rinsing | ammonia | 9 | B | 10 | C |
| Comp. Ex. 2 | Mo | water rinsing | KOH | 9 | B | 8 | C |
| Comp. Ex. 3 | Mo | water rinsing | TMAH | 9 | B | 10 | C |
| Comp. Ex. 4 | Mo | water rinsing | only water | 7 | B | 6 | C |
| Comp. Ex. 5 | W | water rinsing | only water | 7 | B | 7 | C |

As shown in Table 1, Examples 1 to 7, each of which used a specific basic cleaning composition after the water rinsing process, demonstrate that the ability of the basic cleaning composition to dissolve water insoluble matter is good, so that the water insoluble matter produced can be dissolved. Moreover, Examples 1 to 7 exhibit good filter permeability, which confirms that the respective basic cleaning compositions are able to dissolve the water-insoluble matter produced. Further, the basic cleaning compositions of Examples 1 to 7 have excellent cleanability for a substrate, and thus are able to dissolve the water-insoluble matter produced.

### INDUSTRIAL APPLICABILITY

The present disclosure can provide a method for treating a substrate after etching, which allows the water-insoluble matter produced to be dissolved. Therefore, the present disclosure is useful in a method for producing a large-capacity semiconductor memory.

1. A method for treating a substrate after etching, comprising:
cleaning a substrate to be treated with a basic cleaning composition that contains a basic compound and water and has a pH of 10 or more,
wherein the substrate to be treated has a metal layer containing a Group 6 element metal and has been etched with an etchant containing phosphoric acid, nitric acid, water, and an organic amine.

2. The method according to claim 1, wherein the acid contained in the etchant is acid containing phosphoric acid and nitric acid.

3. The method according to claim 1, comprising washing the substrate to be treated with water before the cleaning process.

4. The method according to claim 1, wherein the basic cleaning composition has a pH of 11 or more.

5. The method according to claim 1, wherein the basic compound of the basic cleaning composition includes at least one selected from the group consisting of ammonia, an alkali metal hydroxide, and an organic amine or a salt thereof.

6. The method according to claim 1, wherein a temperature of the cleaning composition in the cleaning process is 0° C. or more and 100° C. or less.

7. The method according to claim 1, wherein a cleaning time in the cleaning process is 10 seconds or more and 120 minutes or less.

8. The method according to claim 1, wherein a temperature (etching temperature) of the etchant in the etching is 0° C. or more and 100° C. or less.

9. The method according to claim 1, wherein an etching time in the etching is 1 minute or more and 180 minutes or less.

10. The method according to claim 1, wherein the Group 6 element metal is at least one selected from the group consisting of chromium (Cr), molybdenum (Mo), tungsten (W), and seaborgium (Sg).

11. The method according to claim 1, wherein an organic amine compound contained in the etchant is at least one organic amine compound selected from the group consisting of polyalkyleneimine, a polymer having a constitutional unit derived from diallylamine, polyalkylene polyamine, alkylamine, alkanolamine, alicyclic amine, aromatic amine, and amino acid.

12. The method according to claim 1, wherein the basic cleaning composition has a pH of 10 or more and 14 or less.
